(19) United States
(12) Patent Application Publication
(10) Pub. No.: US 2026/0267216 A1
(43) Pub. Date: Sep. 10, 2026

(54) OPTICAL PROXIMITY CORRECTION (OPC) METHOD AND MASK MANUFACTURING METHOD INCLUDING THE SAME

(71) Applicant: SAMSUNG ELECTRONICS CO., LTD., Suwon-si (KR)

(72) Inventors: Moojoon Shin, Suwon-si (KR); Jieun KWON, Suwon-si (KR); Yongsu JUNG, Suwon-si (KR); Kyungjae PARK, Suwon-si (KR)

(73) Assignee: SAMSUNG ELECTRONICS CO., LTD., Suwon-si (KR)

(21) Appl. No.: 19/369,781

(22) Filed: Oct. 27, 2025

(30) Foreign Application Priority Data
Mar. 10, 2025 (KR) 10-2025-0030781

(51) Int. Cl. G03F 1/36; G03F 1/70

(52) U.S. Cl. CPC G03F 1/36; G03F 1/70

(57) ABSTRACT

There is provided an optical proximity correction (OPC) method capable of minimizing an edge placement error (EPE) of a curvilinear full-chip mask and a mask manufacturing method including the OPC method. The OPC method includes obtaining a curvy neural Jacobian model through artificial neural network (ANN) learning using learning data, obtaining a first baseline curvilinear mask and reducing a number of vertices of the first baseline curvilinear mask to convert the first baseline curvilinear mask into a multigon mask, extracting first geometric features from the multigon mask, calculating a Jacobian between the multigon mask and edge placement error (EPE) by using the curvy neural Jacobian model and the first geometric features, and optimizing the multigon mask by using the Jacobian.

### CROSS-REFERENCE TO RELATED APPLICATIONS

This present application claims priority to and the benefit under 35 U.S.C. § 119 (a)-(d) of Korean Patent Application No. 10-2025-0030781, filed on Mar. 10, 2025, in the Korean Intellectual Property Office, the entire disclosure of which is incorporated herein by reference.

### BACKGROUND

In a semiconductor process, a photolithography process using a mask may be performed to form a pattern on a semiconductor substrate such as a wafer. A mask may be referred to as a pattern transcript in which an opaque material pattern shape is formed on a transparent base material. To manufacture such a mask, first, a layout for a required pattern is designed, and then OPC layout data obtained through OPC is transferred as mask tape-out (MTO) design data. Then, mask data preparation (MDP) may be performed based on the MTO design data, and an exposure process may be performed thereafter on a mask substrate.

### SUMMARY

The disclosed concepts relate to an optical proximity correction (OPC) method capable of minimizing an edge placement error (EPE) of a curvilinear full-chip mask and a mask manufacturing method including the OPC method.

The technical problems of the disclosed concepts are not limited to the technical problems mentioned above, and other technical problems not mentioned will be clearly understood by those skilled in the art from the description below.

According to aspects of the disclosed concepts, there is provided an OPC method including obtaining a curvy neural Jacobian model through artificial neural network (ANN) learning using learning data, obtaining a first baseline curvilinear mask for a target mask and reducing the number of vertices of the first baseline curvilinear mask to convert the first baseline curvilinear mask into a multigon mask, extracting first geometric features from the multigon mask, calculating Jacobian between the multigon mask and edge placement error (EPE) by using the curvy neural Jacobian model and the first geometric features, and optimizing the multigon mask by using the Jacobian.

According to aspects of the disclosed concepts, there is provided an OPC method including obtaining brute Jacobian by using a learning mask, obtaining learning data from the brute Jacobian, performing artificial neural network (ANN) learning by using the learning data to obtain a curvy neural Jacobian model, receiving data on the target mask, performing curvilinear OPC on the target mask to obtain a first baseline curvilinear mask, reducing the number of vertices of the first baseline curvilinear mask and converting the first baseline curvilinear mask into a multigon mask by using the vertices of the first baseline curvilinear mask, extracting first geometric features from the multigon mask, calculating Jacobian between the multigon mask and edge placement error (EPE) by using the curvy neural Jacobian model and the first geometric features; and optimizing the multigon mask by using the Jacobian.

According to aspects of the disclosed concepts, there is provided a mask manufacturing method including performing an OPC method using a curvy neural Jacobian model on a target mask to obtain an OPC layout, performing optical rule check (ORC) on the OPC layout, transferring a final OPC layout passing the ORC as mask tape-out (MTO) design data, preparing mask data based on the MTO design data, and exposing a mask substrate based on the mask data. In the obtaining of the OPC layout, the curvy neural Jacobian model is obtained through ANN learning and a predicted value by the curvy neural Jacobian model is applied to mask optimization.

### BRIEF DESCRIPTION OF THE DRAWINGS

Embodiments will be more clearly understood from the following detailed description taken in conjunction with the accompanying drawings in which:

FIG. 1 is a flowchart schematically illustrating processes of an optical proximity correction (OPC) method using a curvy neural Jacobian model according to embodiments;

FIG. 2 is a block structure diagram illustrating the OPC method of FIG. 1 in more detail;

FIG. 3 is a conceptual diagram illustrating a change in a peripheral edge placement error (EPE) according to a perturbation of a control point in a multigon mask;

FIGS. 4A and 4B are conceptual diagrams illustrating vertices of a curved mask and a multigon mask;

FIG. 5 is a conceptual diagram illustrating an artificial neural network (ANN) used to generate a curvy neural Jacobian model in the OPC method of FIG. 1;

FIGS. 6A and 6B are conceptual diagrams illustrating approximations of an area and a center of mass of a perturbed multigon mask;

FIGS. 7A and 7B are conceptual diagrams for explaining a concept of geometric features used for ANN learning in the OPC method of FIG. 1;

FIG. 8 is a conceptual diagram illustrating an accelerated mask optimization process considering a change in micro EPE due to a change in micro mask;

FIG. 9 are graphs illustrating performance of a curvy neural Jacobian model;

FIGS. 10A and 10B are graphs illustrating effectiveness of the OPC method of FIG. 1; and

FIG. 11 is a flowchart schematically illustrating processes of a mask manufacturing method including an OPC method according to embodiments.

### DETAILED DESCRIPTION

Hereinafter, embodiments of the inventive concept will be described in detail with reference to the accompanying drawings. Like reference numerals refer to like elements, and their repetitive descriptions are omitted.

The disclosed concepts relate to a mask manufacturing method, and more particularly, to an optical proximity correction (OPC) method and a mask manufacturing method including the same.

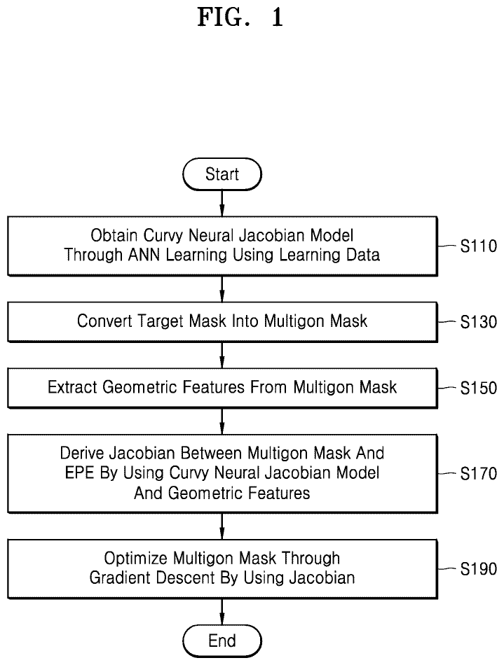

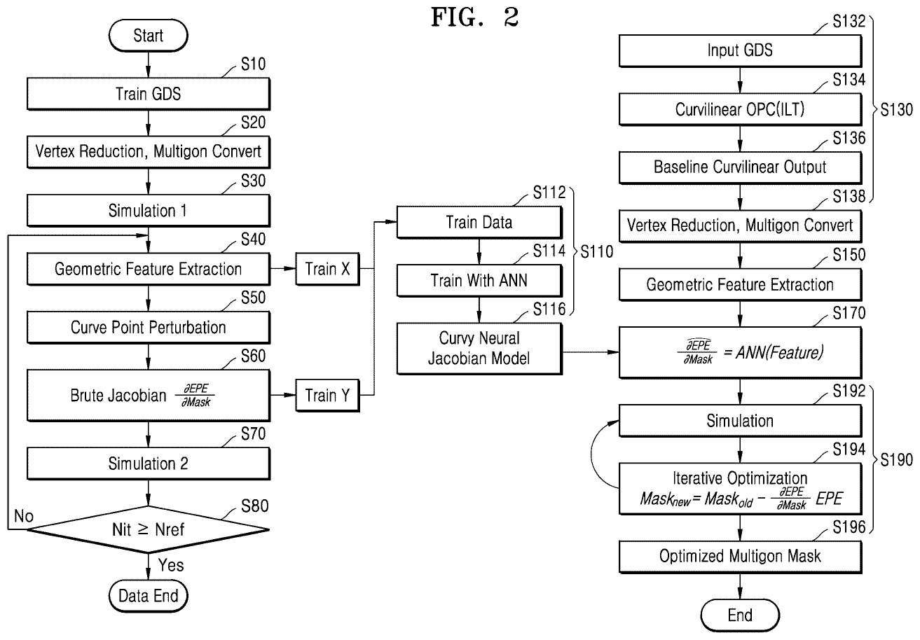

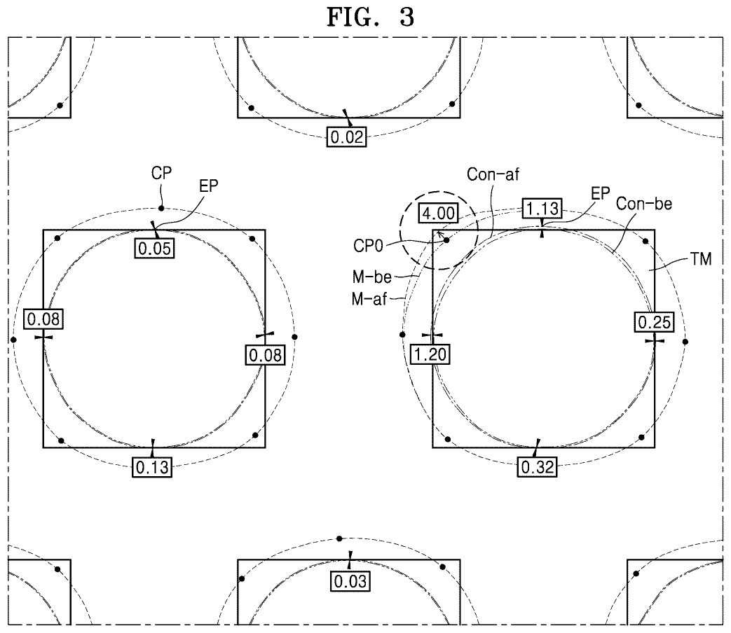

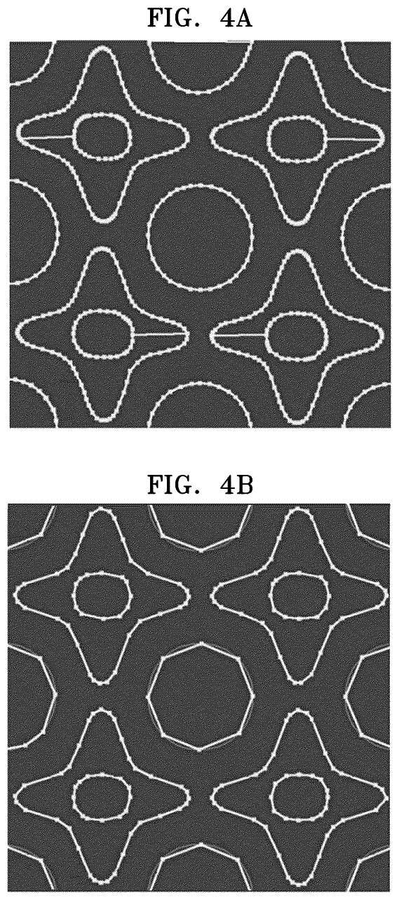

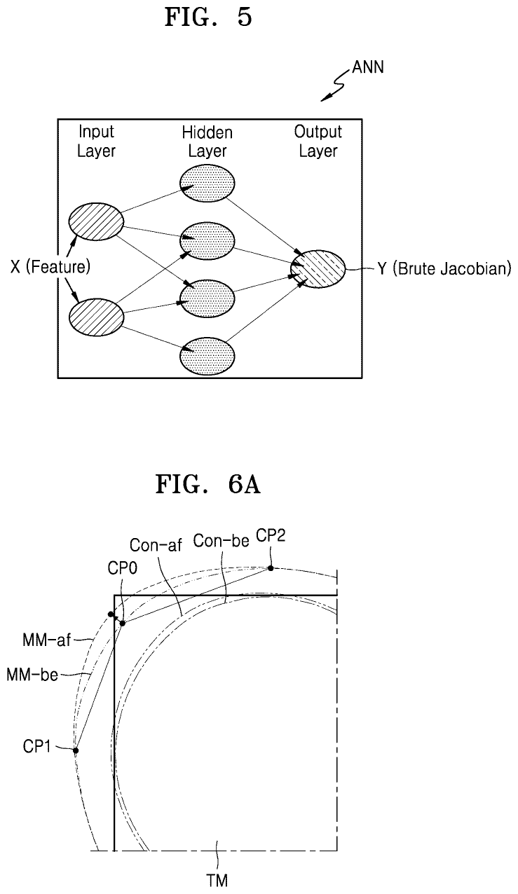

FIG. 1 is a flowchart schematically illustrating processes of an optical proximity correction (OPC) method using a curvy neural Jacobian model according to embodiments and FIG. 2 is a block structure diagram illustrating the OPC method of FIG. 1 in more detail. FIG. 3 is a conceptual diagram illustrating a change in a peripheral edge placement error (EPE) according to a perturbation of a control point in a multigon mask and FIGS. 4A and 4B are conceptual diagrams illustrating vertices of a curved mask and a multigon mask. FIG. 5 is a conceptual diagram illustrating an artificial neural network (ANN) used to generate a curvy neural Jacobian model in the OPC method of FIG. 1.

Referring to FIGS. 1 to 5, in the OPC method using the curvy neural Jacobian model of embodiments (hereinafter, simply referred to as the ‘OPC method’), first, the curvy neural Jacobian model is obtained through ANN learning using learning data in operation S110. In the inventive concept, Jacobian may mean a change dEPE in EPE at a surrounding evaluation point EP according to mask variation dMask, that is, dEPE/dMask. For example, Jacobian may mean a value obtained by applying perturbation to the control points CP of the mask and by measuring or calculating a response at the surrounding evaluation points EP, that is, the change in EPE at the surrounding evaluation points EP. Meanwhile, because there are a plurality of control points CP and a plurality of EPE changes corresponding to the plurality of control points CP are calculated, Jacobian may be represented in the form of a two-dimensional matrix such as dEPEⱼ/dMaskᵢ. Accordingly, Jacobian may also be referred to as a Jacobian matrix.

The control point CP may mean a point at which perturbation is applied to a mask M, and the EPE may mean a value obtained by subtracting a target mask TM from a mask contour Con at the evaluation point EP. Referring to FIG. 3 for a more detailed explanation, the target mask TM means a specific shape of pattern that is to be actually formed on a substrate such as a wafer, and may correspond to a rectangle in FIG. 3. The mask M may mean a pattern on a mask corresponding to the target mask TM, or a layout for the pattern. In FIG. 3, the mask M may correspond to a large outer circle. The mask contour Con as a result of the OPC method may correspond to a small circle in FIG. 3. The purpose of the OPC method may be to make the mask contour Con as similar as possible to the shape of the target mask TM.

Meanwhile, control points CP applying perturbation onto the mask M are indicated as black dots on the mask M in FIG. 3. In addition, in the large circle of FIG. 3, an inner side may correspond to a mask before perturbation M-be and an outer side may correspond to a mask after perturbation M-af. In addition, in the small circle of FIG. 3, an inner side may correspond to a mask contour before perturbation Con-be and an outer side may correspond to a mask contour after perturbation Con-af. The evaluation point EP may mean a point on the target mask TM. For example, in FIG. 3, the evaluation point EP corresponds to the center point of each side of the rectangular target mask TM, and the EPE may be calculated at the evaluation point EP.

In addition, as illustrated in FIG. 3, when perturbation is applied to a control point CP0 of a center-right mask M, a corresponding mask contour Con changes relatively greatly, and therefore, EPEs due to the mask contour Con may also change relatively greatly. In addition, perturbation of the control point CP0 also affects a mask contour Con of surrounding masks M, and accordingly, EPEs of the surrounding masks M may also be slightly changed. In FIG. 3, EPE variation values at evaluation points EP according to the perturbation of the control point CP0 are indicated in small squares. In the case of the surrounding masks M, a change in mask contour Con is subtle so that the mask contour Con appears as one small circle, but the mask contour Con may actually correspond to two small circles.

In the curvy neural Jacobian model, neural means that Jacobian is obtained by using machine learning such as the ANN learning. In addition, the ‘curvy’ may mean that Jacobian is obtained for a curvilinear mask rather than a rectangular mask. For reference, the mask M may be represented in the form of a curve as illustrated in FIG. 3, but the mask M may also be represented in the form of a combination of straight line segments. A mask represented by a combination of such segments is called an orthogonal mask, and Jacobian for a curvilinear mask is called curvy Jacobian in order to distinguish Jacobian for a curvilinear mask from Jacobian for an orthogonal mask.

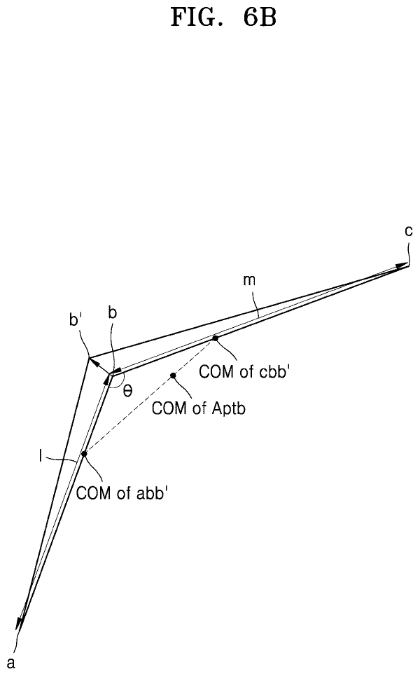

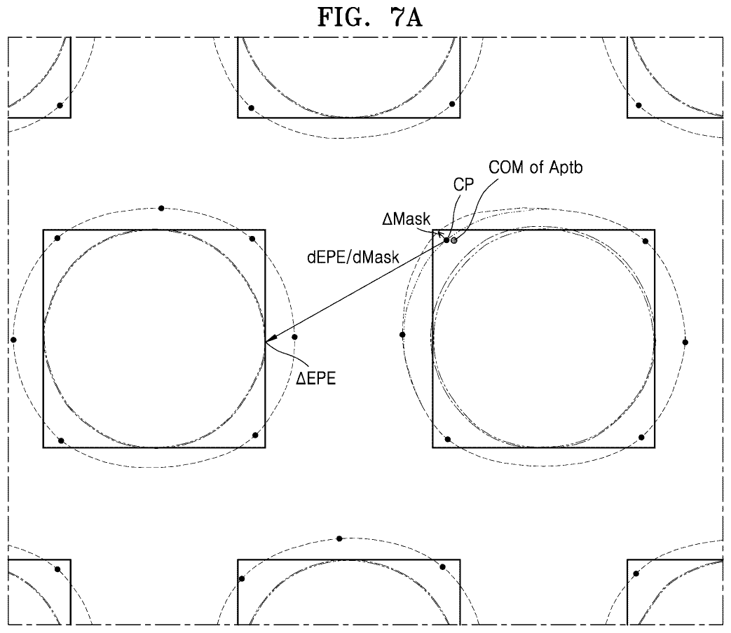

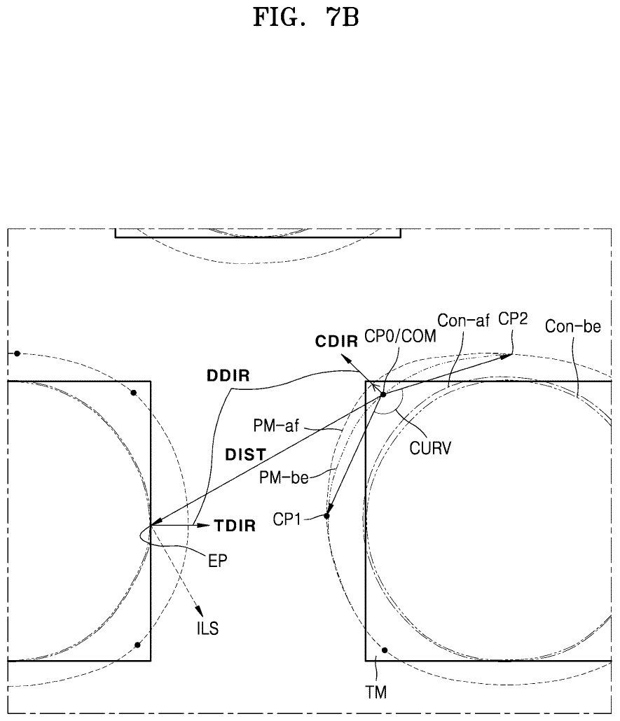

Learning data for producing the curvy neural Jacobian model may include input learning data used as input values in ANN learning, and output learning data used as output values. In the OPC method of embodiments, the input learning data may mean a geometric feature. Here, the geometric feature may mean a relative relationship between a control point CP and surrounding evaluation points EP affected by perturbation of the control point CP. The geometric feature may include, for example, a relative position, a relative angle, and an optical parameter between the perturbation and the evaluation point EP. The geometric features are described in more detail with reference to FIGS. 6A to 7B.

Meanwhile, the output learning data is used as target data or output data in the ANN learning, and may mean actual measured values or calculated values for Jacobian.

Referring to FIG. 2, processes of obtaining the curvy neural Jacobian model is described in more detail as follows.

First, in relation to processes of obtaining learning data, Train GDS is received in operation S10. ‘Train GDS’ may mean graphic data system (GDS) data on a clip that is part of a full-chip. Here, Train means for learning, and GDS data may include information items on, for example, a size and shape of a learning mask. Then, based on the Train GDS, a baseline curvilinear mask may be derived via OPC. For example, a baseline curvilinear mask can be introduced through curvilinear OPC such as inverse lithography technology (ILT). Here, the baseline curvilinear mask may appear to be a curve but may not actually be a curve. For example, as illustrated in FIG. 4, the baseline curvilinear mask may include a combination of fine straight line segments.

Then, vertex reduction is performed on the baseline curvilinear mask, and the baseline curvilinear mask is converted into a multigon mask by using the reduced vertices in operation S20. Vertex reduction may mean a process of reducing the number of vertices by selecting some of the countless vertices of the baseline curvilinear mask. Vertex reduction may be performed, for example, by a distance tolerance method. Here, the distance tolerance method may mean selecting vertices such that line segments between the selected vertices have a distance difference in tolerance from the line segments of the original baseline curvilinear mask, that is, the segments.

Then, a multigon mask is formed by constructing a Bezier curve based on the reduced vertices. That is, the baseline curvilinear mask is converted into the multigon mask. Here, the Bezier curve may correspond to an implicit Bezier curve, for example, including only two vertices. In FIG. 4B, thin curves between the vertices may correspond to Bezier curves.

Then, a first OPC simulation is performed on the multigon mask in operation S30. The first OPC simulation may be used to calculate the mask contour corresponding to the multigon mask, and also to calculate the EPE. Here, the first OPC simulation may mean the OPC simulation before perturbation for the multigon mask.

Next, the geometric features are extracted from the multigon mask in operation S40. The geometric features, as described above, may imply a relative relationship between the control points of the multigon mask and surrounding evaluation points EP affected by perturbation of the control points.

The geometric features are described in more detail with reference to FIGS. 6A to 7B. Meanwhile, the geometric features may constitute input learning data Train X in the ANN learning to derive the curvy neural Jacobian model.

Continuously, at the control points of the multigon mask, curve point perturbation is performed in operation S50. The curve point perturbation may mean deforming a curve shape of the multigon mask through fine movement of the control points. Next, brute Jacobian between the multigon mask and the EPE dEPE/dMask is calculated in operation S60.

The brute Jacobian dEPE/dMask may be calculated as an accurate value because the brute Jacobian dEPE/dMask is calculated based on the variation of the actual mask dMask and the resulting variation of the actual EPE dEPE. The brute Jacobian may constitute output learning data Train Y in the ANN learning to derive the curvy neural Jacobian model.

However, in the case of the mask perturbation of the multigon mask, the following problems may occur. Because the baseline curvilinear mask of FIG. 4A includes uniformly spaced vertices and uniform segments, it is easy to derive optimal movement of segments for minimizing the surrounding EPE. However, in the case of the multigon mask of FIG. 4B, because vertices are not uniformly apart from one another and are irregularly distributed, it is difficult to derive optimal movement of vertices for minimizing the surrounding EPE. Here, moving vertices may correspond to control points. Accordingly, in the OPC method of embodiments, in order to accurately infer a change in EPE dEPEᵢ at surrounding evaluation points, that is, a value of Jacobian dEPEⱼ/dMaskⱼ when irregular control points move in a normal direction dMaskⱼ, the concept of the center of mass and area of perturbation is introduced. That is, the geometric features are extracted by using the center of mass of the perturbation rather than the control points, and Jacobian is also calculated by using the concept of normalized area. The concept of center of mass and area of perturbation is described in more detail with reference to FIGS. 6A and 6B.

Then, a second OPC simulation is performed on the multigon mask in operation S70. The second OPC simulation may be used to calculate the mask contour corresponding to the multigon mask, and also to calculate the EPE. Here, the second OPC simulation may mean the OPC simulation after perturbation for the multigon mask.

Next, it is determined whether the number of repetitions Nit is the reference number of repetitions Nref or more in operation S80. Here, the reference number of repetitions Nref may be set to a sufficient number of repetitions to extract learning data on the ANN learning. When it is determined that the number of repetitions Nit is the reference number of repetitions Nref or more YES, the process of extracting learning data Train X and Train Y is terminated. When it is determined that the number of repetitions Nit is less than the reference number of repetitions Nref NO, the process proceeds to operation S40 of extracting the geometric features and the following operations are repeated.

In some embodiments, instead of determining the number of repetitions in operation S40, it may be determined whether the calculated EPE is a reference EPE or less. Perturbation after the calculated EPE becomes the required reference EPE may be meaningless in the ANN learning.

Through the above process, the learning data Train X and Train Y used for the ANN learning may be extracted. Then, the learning data Train X and Train Y is input to the ANN in operation S112 and the ANN learning is performed based on the learning data in operation S114. The curvy neural Jacobian model is derived through learning in operation S116.

The ANN is described in more detail with reference to FIG. 5 as a network simulating biological neural networks. In FIG. 5, for convenience of explanation, the ANN is depicted as including one hidden layer. However, the inventive concept is not limited thereto and the ANN may include a variable number of hidden layers.

In FIG. 5, the hidden layer is illustrated as including four nodes, but the number of nodes included in the hidden layer is not limited thereto. For example, the hidden layer may include tens or hundreds of nodes. In the OPC method of embodiments, for example, the hidden layer may include about 100 nodes. In addition, in FIG. 5, the ANN is illustrated as including an input layer of two separate nodes for receiving input data, but according to embodiments, the input data may be input directly to the hidden layer without an input layer. In addition, according to embodiments, the input layer may include three or more nodes.

In the ANN, nodes in layers other than an output layer may be connected to nodes in the next layer through links for transmitting output signals. Through the links, values obtained by multiplying node values of nodes included in the previous layer by weights assigned to each link may be input to one node. The node values in the previous layer may correspond to axon values, and the weights may correspond to synaptic weights. The weights may be referred to as parameters of the ANN. Activation functions include a sigmoid function, a hyperbolic tangent (tanh) function, and a rectified linear unit (ReLU) function, and nonlinearity may be implemented in the neural network through the activation function.

An output of any node included in the ANN may be represented as in Equation (1) below.

$${y}_{i} = f ( {\sum }_{j = 1}^{m} {w}_{j , i} {x}_{j} ) \qquad Equation ( 1 )$$

Equation (1) may represent an output value yᵢ of an ith node for m input values in any layer. xⱼ may represent an output value of a jth node of the previous layer, and w_{j,i} may represent a weight applied to a connection between the jth node of the previous layer and the ith node of the current layer. f( ) may represent an activation function. As illustrated in Equation (1), the cumulative result of the multiplication of the input value xⱼ and the weight w_{j,i} may be used in the activation function. In other words, an operation of multiplying the input value xj by the weight w_{j,i} and adding the results, that is, a multiply accumulate (MAC) operation at each node, may be performed.

Meanwhile, a neural model may be generated through the ANN learning. In other words, the neural model is generated through the ANN learning, and when a specific value is input to the neural model, a corresponding predicted value or result value may be output. For example, in the OPC method of embodiments, the input value of the ANN learning may be input learning data Train X, that is, the geometric features, and the output value may be output learning data Train Y, that is, Brute Jacobian. In addition, the curvy neural Jacobian model may be obtained through the ANN learning. When data corresponding to the input learning data is input to the obtained curvy neural Jacobian model, the predicted value corresponding to the output learning data may be calculated and output.

After obtaining the curvy neural Jacobian model, the target mask TM is converted into the multigon mask through the process of obtaining the baseline curvilinear mask and reducing the vertices of the baseline curvilinear mask in operation S130. The process of converting the target mask TM into the multigon mask may be substantially the same as the process of converting a learning mask into the multigon mask. Here, the target mask TM may actually mean a pattern to be formed on a substrate.

Operation S130 of converting the target mask TM into the multigon mask will be described in more detail with reference to FIG. 2. First, the GDS data on the target mask TM is received in operation S132. The GDS data on the target mask TM may mean the GDS data on the full-chip. Then, based on the GDS data, the curvilinear OPC is performed in operation S134. The curvilinear OPC may be performed, for example, through the ILT. The baseline curvilinear mask is generated through the curvilinear OPC in operation S136. Then, vertex reduction is performed on the baseline curvilinear mask, and the baseline curvilinear mask is converted into the multigon mask by using the reduced vertices in operation S138. The process of converting the baseline curvilinear mask into the multigon mask may be substantially the same as the process of converting the baseline curvilinear mask into the multigon mask for the learning mask. From operation S132 of receiving the GDS data to operation S138 of converting the baseline curvilinear mask into the multigon mask may correspond to operation S130 of converting the target mask TM into the multigon mask.

Then, the geometric features are extracted from the multigon mask in operation S150. The geometric features, as described above, may imply a relative relationship between the control points of the multigon mask and the surrounding evaluation points EP affected by perturbation of the control points. The geometric features are described in more detail with reference to FIGS. 6A to 7B. Here, the geometric features may correspond to the geometric features used to derive predicted Jacobian by inputting the geometric features to the curvy neural Jacobian model obtained through previous ANN learning.

Therefore, the extracted geometric features are input to the curvy neural Jacobian model to produce Jacobian Jacobian_{i,j} in operation S170. Here, the Jacobian Jacobian_{i,j} as the output of the curvy neural Jacobian model, may correspond to the predicted value corresponding to the output learning data of the ANN (Brute Jacobian), that is, predicted Jacobian. In FIG. 2, the hat on dEPE in the block of S170 may mean that Jacobian Jacobian_{i,j} is a predicted value rather than an exactly calculated value. Jacobian Jacobian_{i,j} may be calculated as illustrated in Equation (2) below.

$${Jacobian}_{i , j} = {dEPE}_{i} / {dMask}_{j} \approx ANN ( Feature ) * ECL \qquad Equation ( 2 )$$

Here, ANN (Feature) refers to the output value of the ANN, and may correspond to the predicted Jacobian output when the geometric feature is input to the neural Jacobian model. Meanwhile, in the ANN learning, area normalized Brute Jacobian may be used as output learning data. Accordingly, the area must be multiplied to obtain the original Brute Jacobian. In addition, the area may be approximated to an effective curve length (ECL) by approximating fine fluctuation of a mask to 0, and accordingly, by multiplying the ECL by the ANN (Feature), accurate predicted Jacobian may be calculated. The calculation of Jacobian through specific equations is described in more detail with reference to FIGS. 6A and 6B.

After calculating Jacobian, optimization of the multigon mask is performed by using Jacobian in operation S190. For the optimization of the multigon mask, gradient descent may be used, for example. Accordingly, mask optimization using Jacobian may be expressed as the following Equation (3) by gradient descent.

$${Mask}_{new} = {Mask}_{old} - α {\sum }_{i} ( {dEPE}_{i} / {dMask}_{j} ) * {EPE}_{i} \qquad Equation ( 3 )$$

In Equation (3), α may correspond to a constant related to a learning rate. Meanwhile, because Jacobian may be approximated as the output value of the ANN by Equation (2), Equation (3) may be expressed as Equation (4).

$${Mask}_{new} = {Mask}_{old} - α {\sum }_{i} ( ANN ( Feature ) * ECL ) * {EPE}_{i} \qquad Equation ( 4 )$$

The mask optimization operation S190 may include operation S192 of obtaining the EPE through OPC simulation, operation S194 of optimizing the mask by the gradient descent, and operation S196 of deriving an optimized multigon mask. Operation S196 of deriving the optimized multigon mask may be implemented by minimizing the EPE by repeating operation S192 of obtaining the EPE and operation S194 of optimizing the mask by the gradient descent tens to hundreds of times.

Meanwhile, assuming that Jacobian predicted by using the ANN (that is, predicted Jacobian used by the curvy neural Jacobian model obtained through the ANN learning) is very accurate, accelerated mask optimization may be applied, and an EPE change according to mask variation is expressed as in the following Equation (5), through which the EPE may be reduced by using less simulation time

$${EPE}_{predicted} = {EPE}_{true} + {\sum }_{i} ( {dEPE}_{i} / {dMask}_{j} ) * dMask \qquad Equation ( 5 )$$

Here, EPE_{predicted} may mean the predicted value for the EPE change according to the mask variation, and EPEₜᵣᵤₑ may mean the current EPE.

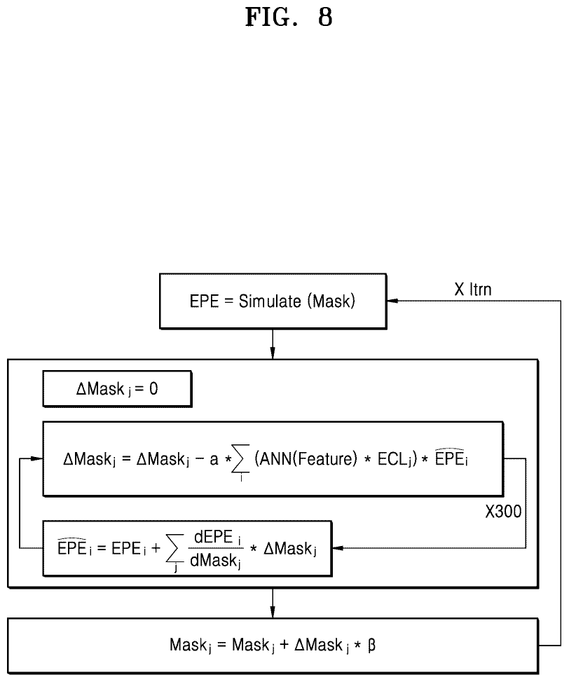

The accelerated mask optimization is described in more detail with reference to FIG. 8. In the OPC method of embodiments, the EPE may be minimized while sufficiently implementing vertex reduction by using the multigon mask. For example, by obtaining the baseline curvilinear mask through the ILT, by reducing the number of vertices of the baseline curvilinear mask and converting the baseline curvilinear mask into the multigon mask using the vertices, and then by performing mask optimization by using the curvy neural Jacobian model, it is possible to proceed with minimizing the EPE while minimizing an amount of calculation as much as possible. In addition, by introducing the concept of center of mass and area of perturbation, extracting the geometric features as the learning data, and using such learning data for the ANN learning, the curvy neural Jacobian model with excellent performance may be obtained despite uneven spacing of vertices of the multigon mask. Therefore, Jacobian may be accurately predicted through the curvy neural Jacobian model. Furthermore, by applying the accelerated mask optimization, it is possible to minimize the EPE with a small number of repetitions and to minimize the amount of calculation. For example, when performing a general curvilinear OPC method, a capacity of 60 GB is required, but in the case of the OPC method of embodiments, the capacity may be significantly reduced to about 23 GB.

For reference, the OPC method of embodiments may be related to an optical OPC model in a general OPC method. The general OPC method is divided into two types: one is a rule-based OPC method, and the other is a simulation-based or model-based OPC method. The model-based OPC method may be advantageous in terms of time and cost because only the measurement results of representative patterns are used without measuring all of the large number of test patterns.

Meanwhile, the general OPC method may include not only a variation of a layout of a pattern, but also a method of adding sub-lithographic features called serifs on the corners of the pattern, or a method of adding sub-resolution assist features (SRAFs) such as scattering bars.

The general OPC method involves first preparing basic data for OPC. Here, the basic data may include data on a shape of patterns of a sample, a position of the patterns, a type of measurement such as a measurement on a space or line of a pattern, and a basic measurement value. In addition, the basic data may include information such as thickness, refractive index, and dielectric constant of photoresist (PR), and a source map for a type of illumination system. The basic data is not limited to the data exemplified above.

After preparing the basic data, an optical OPC model is generated. Generation of the optical OPC model may include optimization of a defocus stand (DS) position and a best focus (BF) position during an exposure process. In addition, the generation of the optical OPC model may include generation of an optical image considering a diffraction phenomenon of light or an optical state of exposure equipment. The generation of the optical OPC model is not limited thereto. For example, the generation of the optical OPC model may include various contents related to optical phenomena in the exposure process.

After generating the optical OPC model, an OPC model for PR is generated. The generation of the OPC model for PR may include optimization of a threshold value of PR. Here, the threshold value of PR means a threshold value at which a chemical change occurs in the exposure process, and for example, the threshold value may be given as intensity of exposure light. The generation of the OPC model for PR may also involve selecting an appropriate model form from several PR model forms.

The optical OPC model and the OPC model for PR are combined and are generally referred to as the OPC model. After generating the OPC model, simulation is performed using the OPC model to generate an OPC layout. Previously, OPC simulation may correspond to simulation using the optical OPC model.

FIGS. 6A and 6B are conceptual diagrams illustrating approximations of an area and center of mass of a perturbed multigon mask. FIG. 6B illustrates a shape approximating the perturbed portion of FIG. 6A to a square shape. The center control point CP0 before perturbation in FIG. 6A corresponds to a vertex b in the square in FIG. 6B, control points CP1 and CP2 adjacent to the center control point CP0 on both sides correspond to vertices a and c in the square in FIG. 6B, and the control point CP0 after perturbation corresponds to a vertex b′ in the square in FIG. 6B.

Referring to FIGS. 6A and 6B, in FIG. 6B, when a length of a side between the vertices a and b is 1 and a length of a side between the vertices b and c is m, the center of mass of a first triangle formed by the vertices a, b, and b′ according to perturbation may be positioned inside the first triangle, and the center of mass of a second triangle formed by the vertices b, b′, and c according to perturbation may be positioned inside the second triangle. When the mask variation dMask is nearly 0, that is, the perturbation of the central control point CP0 is very small, a length of a side between the vertices b and b′ may be negligibly small compared to 1 and m. In addition, the center of mass may be approximated to a point on the side between the vertices a and b for the first triangle, and to a point on the side between the vertices b and c for the second triangle. In FIG. 6B, the center of mass COM of abb′ of the first triangle is indicated as a dot on the side between the vertices a and b, and the center of mass COM of cbb′ of the second triangle is indicated as a dot on the side between the vertices b and c. By applying a similar approximation concept to the center of mass of the first triangle COM of abb′ and the center of mass of the second triangle COM of cbb′, the center of mass of the area COM of Aptb due to perturbation is approximated to a point on the dotted line connecting the center of mass of the first triangle COM of abb′ and the center of mass of the second triangle COM of cbb′, and is indicated as a point in FIG. 6B.

For reference, calculation of the center of mass of the area COM of Aptb according to perturbation may be calculated by the following Equation (6).

$$COM of Aptb = [ 1 * \{ ( 1 - 1 / {2}^{1 / 2} ) * a + ( 1 / {2}^{1 / 2} ) * b \} + m * \{ ( 1 - 1 / {2}^{1 / 2} ) * c + ( 1 / {2}^{1 / 2} ) * b \} ] / ( 1 + m ) \qquad Equation ( 6 )$$

Meanwhile, when the mask variation dMask is almost 0, the area due to perturbation may be approximated to the ECL. The ECL may be calculated by the following Equation (7).

$$ECL = 0.5 * \{ 1 * sin ( θ / 2 ) + m * sin ( θ / 2 ) \} \qquad Equation ( 7 )$$

Here, θ may correspond to an angle formed by line segments when connecting the central control point CP0 to the adjacent control points CP1 and CP2, as illustrated in FIG. 6B. θ may correspond to one of the geometric features. In the OPC method of embodiments, the geometric features may be defined by a relative relationship between the center of mass of the mask variation dMask and adjacent evaluation points EP, rather than the control points. As a result, a curvy neural Jacobian model with excellent performance may be generated, and furthermore, accuracy of the predicted value may be improved through the curvy neural Jacobian model.

FIGS. 7A and 7B are conceptual diagrams for explaining a concept of geometric features used for ANN learning in the OPC method of FIG. 1 and FIG. 7B is an enlarged view of part of FIG. 7A.

Referring to FIGS. 7A and 7B, FIG. 7A schematically illustrates EPE variation ΔEPE at one evaluation point on the target mask adjacent to the left according to mask variation ΔMask, and FIG. 7B enlarges the corresponding part to show concept of the geometric features. In the OPC method of embodiments, eight-dimensional elements of TDIR, CDIR, e^{(-(DIST))}, e^{-(DX)}, e^{-(DY)}, DDIR, an image log slope (ILS), and CUIR may be defined as the geometric features. Specifically, when elements of the geometric features are specifically described, TDIR means an absolute value of a y component of a normal vector TDIR of the evaluation point EP abs (TDIR·y). Here, bold letters mean the vector, and abs means the absolute value. The same applies below.

CDIR means an absolute value of a y component of a normal vector CDIR of the center of mass COM abs (CDIR·y). For reference, the center of mass COM is indicated as the same point as the control point CP0 in FIG. 7B for convenience, but as may be noted in FIG. 6B, positions of the control point CP0 and the center of mass COM may be slightly different.

e^{(-(DIST))} may mean an exponential value having an absolute value ∥DIST∥=DIST of a distance vector DIST from the center of mass COM to the evaluation point EP as a (−) exponent value.

e^{-(DX)} means an exponential value having the absolute value of the x component of the distance vector DIST abs(DIST·x)=DX as a (−) exponent value, and e^{-(DY)} means an exponential value having the absolute value of the y component of the distance vector DIST abs(DIST·y)=DY as a (−) exponent value.

DDIR means an angle between the normal vector of the evaluation point EP TDIR and the normal vector of the center of mass COM CDIR, and may be expressed as follows. DDIR=(TDIR·CDIR)/∥TDIR∥*∥CDIR∥, wherein, “∥ ∥” is an absolute value symbol for a vector.

ILS is an image log slope at the evaluation point, and CURV as the curvature of the mask contour, may be derived from θ in FIG. 6B above.

Meanwhile, in the OPC method of embodiments, the eight-dimensional elements are described as the geometric features, but the geometric features are not limited thereto. For example, the geometric features may be defined in various ways to derive the curvy neural Jacobian model with excellent performance through the ANN. Therefore, the geometric features may be defined in less than 8 dimensions or in more than 8 dimensions.

FIG. 8 is a conceptual diagram illustrating an accelerated mask optimization process considering a micro change in EPE due to a micro change in mask.

Referring to FIG. 8, optimization of the mask may be performed through the Equation (4) above. In FIG. 8, ΔMask is written instead of dMask in the middle box of the large box, and EPEi is written as a predicted value [symbol] by the curvy neural Jacobian model. In addition, the predicted value [symbol] may be calculated by Equation (5) considering the micro change in the EPE according to the micro change in mask. Therefore, the predicted value [symbol] and mask variation ΔMaskⱼ may be precisely calculated by repeating the process in the large box. When the process of Equation (4) is called the mask optimization process, the process of optimizing the mask using Equation (5) is called the accelerated mask optimization process. X300 in a big box could mean 300 repetitions. However, the number of repetitions is not limited to 300.

Then, the mask variation ΔMaskⱼ may be used to calculate the mask Maskⱼ in the last box. Then, the mask contour and EPE for the mask Maskⱼ calculated through OPC simulation in the first box may be calculated. In this way, by first precisely calculating the predicted value [symbol] and the mask variation ΔMaskⱼ through the accelerated mask optimization process of the intermediate box, the number of total repetitions X Itrn may be minimized.

For reference, to minimize the EPE, the entire simulation process of obtaining the EPE in FIG. 8 may be repeated X Itrn. However, in the accelerated mask optimization process, performing sufficient repetitions to obtain the optimal mask and then proceeding with the entire simulation process may be advantageous in terms of speed and accuracy in EPE minimization. For example, in the OPC method of embodiments, in order to minimize the EPE, the accelerated mask optimization process may be repeated about 300 times, and the entire simulation process may be repeated about 10 times. The numbers of repetitions of the accelerated mask optimization process and the entire simulation process are not limited to the aforementioned numbers.

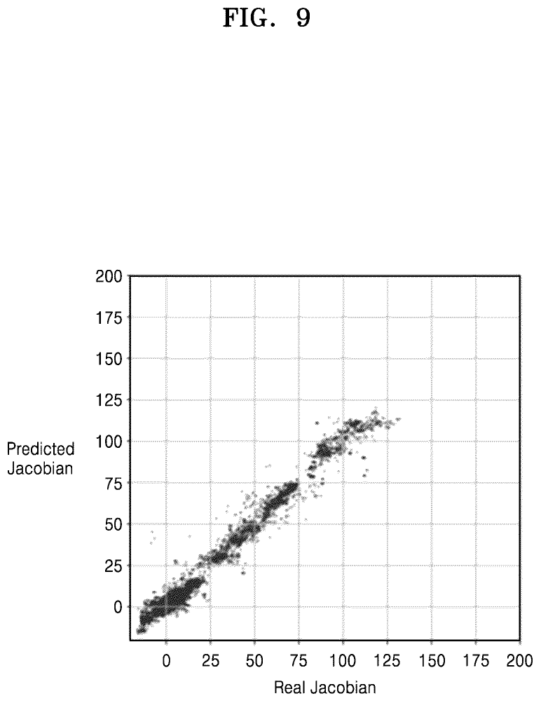

FIG. 9 are graphs illustrating performance of a curvy neural Jacobian model. The x-axis represents an actual Jacobian value actually obtained through measurement, and the y-axis represents a Jacobian value predicted by the neural Jacobian model, and both are unitless.

In the graph of FIG. 9, an R2 coefficient of determination is 0.98, which is close to 1. Therefore, it may be noted that the neural Jacobian model and the predicted value according to the neural Jacobian model have very high consistency.

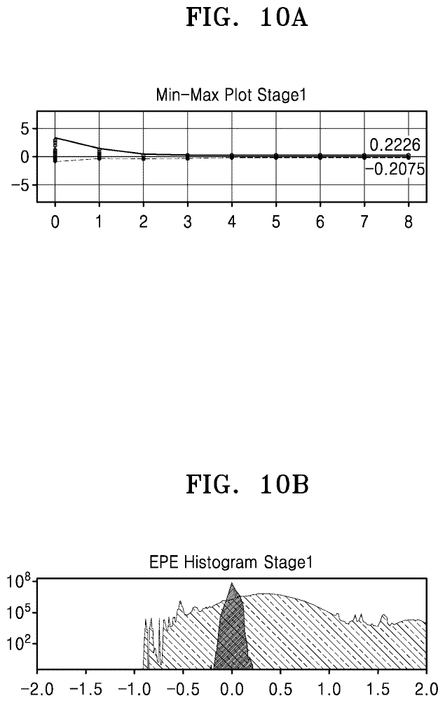

FIGS. 10A and 10B are graphs illustrating effectiveness of the OPC method of FIG. 1.

Referring to FIG. 10A, in the graph of FIG. 10A, the x-axis represents the total number of simulation repetitions of FIG. 8, and the y-axis represents the EPE value. In addition, the solid line represents the maximum value Max of the EPE value, and the dotted line represents the minimum value Min of the EPE value. As may be noted from the graph in FIG. 10A, the EPE value decreases as the number of repetitions increases. Specifically, after converting the baseline curvilinear mask into the multigon mask, the EPE value, which is around 1 to 3 at 0 repetitions, may be reduced around −0.2075 to 0.2226 through 8 repetitions. Therefore, it may be noted the final EPE value is reduced to 1/10 of the initial EPE value.

Referring to FIG. 10B, in the graph of FIG. 10B, the x-axis represents the EPE value and the y-axis represents the number of evaluation points. In addition, light hatching indicates distribution of the EPE according to the OPC method of a comparative example, and dark hatching indicates distribution of the EPE according to the OPC method of embodiments. As may be noted from the graph in FIG. 10B, in the EPE distribution according to the OPC method of embodiments, it may be confirmed that the EPE for most evaluation points is minimized and approaches 0.

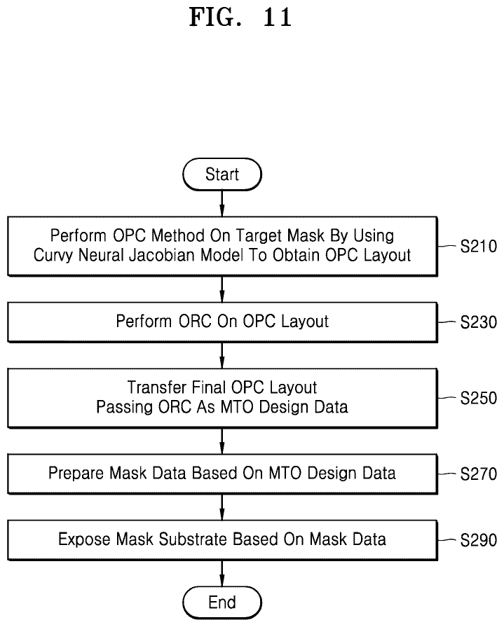

FIG. 11 is a flowchart schematically illustrating processes of a mask manufacturing method including an OPC method according to embodiments. Description previously given with reference to FIGS. 1 to 10B is simply given or omitted.

Referring to FIG. 11, a mask manufacturing method including an OPC method (hereinafter, simply referred to as a ‘mask manufacturing method’), first, performs an OPC method using a curvy neural Jacobian model on a target mask to obtain an OPC layout in operation S210. The OPC method using the curvy neural Jacobian model is as described with reference to FIGS. 1 to 5. Meanwhile, the OPC layout may correspond to a mask layout with minimized EPE obtained through the OPC method using the curvy neural Jacobian model.

After generating the OPC layout, optical rule check (ORC) is performed on the OPC layout in operation S230. ORC may include, for example, root mean square (RMS) calculation for CD error, EPE calculation, pinch error checking, and bridge error checking. However, the items tested in ORC are not limited to the items mentioned above.

In performing ORC, it is determined whether a defect exists. The defect may correspond to cases in which the RMS for the CD error is greater than a set reference value, the EPE is greater than a set reference value, the pinch error exists, and the bridge error exists. In addition, when there are other items in ORC, it may also be a defect when the corresponding items deviate from the reference.

In performing ORC, when a defect exists, the process proceeds to operation S210 of generating the OPC layout according to the cause. Therefore, before proceeding to operation S210 of generating the OPC layout, operation of analyzing the cause of the defect and reflecting the cause in the corresponding OPC model may be performed first.

In performing ORC, when no defect exists, the OPC layout is determined as the final OPC layout, and the final OPC layout image is transferred to the mask manufacturing team as mask tape-out (MTO) design data in operation S250. In general, MTO may mean handing over the final mask data obtained by the OPC method to the mask manufacturing team and requesting mask manufacturing. Therefore, the MTO design data may ultimately be substantially identical to data on the final OPC layout image obtained by the OPC method. The MTO design data may have a graphic data format used in electronic design automation (EDA) software. For example, the MTO design data may have data formats such as graphic data system II (GDS2) and open artwork system interchange standard (OASIS).

Then, mask data preparation (MDP) is performed in operation S270. MDP may include i) format conversion, called fracturing, for example, ii) augmentation of barcodes for machine reading, standard mask patterns for inspection, and job deck, and iii) verification, both automatic and manual. Here, job deck may mean creating a text file including a series of instructions for placement information of multiple mask files, reference dose, and an exposure speed or method.

Meanwhile, format conversion, that is, fracturing may mean the process of dividing the MTO design data into each region and changing the MTO design data into a format for electron beam exposure. Division may include data manipulations such as scaling, sizing, rotating data, reflecting patterns, and inverting colors. During the conversion process through division, data on numerous systematic errors that may occur somewhere during the transfer process from design data to an image on the wafer may be corrected. The data correction process for the systematic errors is called mask process correction (MPC), and may include tasks such as line width adjustment called CD adjustment and improving pattern placement precision. Therefore, division may contribute to improving quality of the final mask and may also be a process performed in advance for MPC. Here, systematic errors may be caused by distortions occurring in the exposure process, a mask development and etching process, and a wafer imaging process.

Meanwhile, MDP may include MPC. As described above, MPC is a process of correcting systematic errors, that is, errors that occur during the exposure process. Here, the exposure process may be a concept comprehensively including electron beam writing, development, etching, and baking. In addition, data processing may be performed before the exposure process. Data processing as a kind of preprocessing process for mask data may include grammar checking for the mask data and exposure time prediction.

After performing MDP, a mask substrate is exposed based on the mask data in operation S290. Here, exposure may mean, for example, electron beam writing. Here, electron beam writing may be performed by, for example, a gray writing method using a multi-beam mask writer (MBMW). In addition, electron beam writing may also be performed by using a variable shape beam (VSB) exposure device.

Meanwhile, after performing MDP, a process of converting the mask data into pixel data may be performed before the exposure process. The pixel data as data directly used for actual exposure may include data on the shape to be exposed and data on the dose assigned to each shape. Here, the data on the shape may be bit-map data obtained by converting shape data that is vector data through rasterization. After the exposure process, a series of processes are performed to complete the mask.

The series of processes may include, for example, developing, etching, and cleaning. In addition, a series of processes for mask manufacturing may include a metrology process and a defect inspection or defect repair process. In addition, a pellicle application process may be included. Here, the pellicle application process may mean a process of attaching a pellicle to the mask surface to protect the mask from subsequent contamination during delivery and the mask's usable lifespan, when the final washing and inspection have confirmed that there are no contaminants or chemical stains.

The mask manufacturing method of embodiments may adopt the OPC method using the curvy neural Jacobian model. Accordingly, by obtaining the curvy neural Jacobian model through the ANN learning and utilizing the curvy neural Jacobian model for mask optimization, time for performing the entire OPC may be accelerated and the EPE may be minimized. Specifically, the multigon mask is obtained and perturbation is performed at the control points to obtain input learning data that are geometric features (relative coordinates, relative angles, and optical parameters) and output learning data that are brute Jacobian dEPE/dMask in large quantities as learning data, and the curvy neural Jacobian model may be generated by using the learning data in the ANN learning. In addition, by introducing the concept of center of mass to the perturbation of the control points, the curvy neural Jacobian model with excellent performance for the multigon mask may be obtained. By performing mask optimization through gradient descent using the predicted value by the curvy neural Jacobian model, the EPE may be minimized through a small number of repetitions, and the amount of calculation may also be minimized.

While the inventive concept has been particularly shown and described with reference to embodiments thereof, it will be understood that various changes in form and details may be made therein without departing from the spirit and scope of the following claims.

What is claimed is:

1. An optical proximity correction (OPC) method comprising:
obtaining a curvy neural Jacobian model through artificial neural network (ANN) learning using learning data;
obtaining a first baseline curvilinear mask for a target mask and reducing a number of vertices of the first baseline curvilinear mask to convert the first baseline curvilinear mask into a multigon mask;
extracting first geometric features from the multigon mask;
calculating a Jacobian between the multigon mask and edge placement error (EPE) by using the curvy neural Jacobian model and the first geometric features; and
optimizing the multigon mask by using the Jacobian.

2. The OPC method of claim 1, wherein the obtaining of the curvy neural Jacobian model comprises:
obtaining a brute Jacobian for a learning mask;
extracting the learning data from the brute Jacobian;
performing ANN learning by using the learning data; and
deriving the curvy neural Jacobian model.

3. The OPC method of claim 2, wherein the obtaining of the brute Jacobian comprises:
receiving data on the learning mask;
obtaining a second baseline curvilinear mask for the learning mask;
reducing a number of vertices of the second baseline curvilinear mask and converting the second baseline curvilinear mask into a learning multigon mask by using the vertices of the second baseline curvilinear mask;
performing a first OPC simulation on the learning multigon mask;
extracting second geometric features from the learning multigon mask;
performing curve point perturbation at a control point of the learning multigon mask;
performing a second OPC simulation on the learning multigon mask; and
deriving the brute Jacobian between the learning multigon mask and EPE,
wherein, after the deriving of the brute Jacobian, when a set criterion is satisfied, the obtaining of the brute Jacobian ends, and when a set criterion is not satisfied, the obtaining of the brute Jacobian proceeds to extracting the second geometric features.

4. The OPC method of claim 3, wherein:
the second geometric features are used as input learning data of the ANN learning, and
wherein the brute Jacobian is used as output learning data of the ANN learning.

5. The OPC method of claim 3, wherein the second geometric features are obtained based on a relative relationship between a control point of the learning multigon mask and a surrounding evaluation point affected by perturbation of the control point.

6. The OPC method of claim 5, wherein a center of mass and an area for the perturbation are obtained, and the second geometric features are obtained by using relative coordinates, relative angles, and optical parameters of the surrounding evaluation point from the center of mass.

7. The OPC method of claim 5, wherein the second geometric features comprise:
an absolute value of a y component of a normal vector of the evaluation point,
an absolute value of a y component of a normal vector of a center of mass of the perturbation,
an exponential value having an absolute value of a distance vector from the center of mass to the evaluation point as a (−) exponent value,
an exponential value having an absolute value of an x component of the distance vector as a (−) exponent value,
an exponential value having an absolute value of a y component of the distance vector as a (−) exponent value,
an angle between the normal vector of the evaluation point and the normal vector of the control point,
an image log slope at the evaluation point, and
a curvature of a mask contour.

8. The OPC method of claim 5, wherein:
an area of the perturbation is approximated to an effective curve length,
the output learning data corresponds to area normalized Jacobian,
the area normalized Jacobian is calculated by using the effective curve length, and
the brute Jacobian is calculated by multiplying an output value of the ANN learning by the effective curve length.

9. The OPC method of claim 1, wherein the converting of the first baseline curvilinear mask into the multigon mask comprises:
receiving data on the target mask;
performing a curvilinear OPC on the target mask to obtain the first baseline curvilinear mask; and
reducing the number of vertices of the first baseline curvilinear mask and converting the first baseline curvilinear mask into the multigon mask by using the vertices of the first baseline curvilinear mask.

10. The OPC method of claim 1, wherein, in the optimizing of the multigon mask, the multigon mask is optimized by using gradient descent.

11. An optical proximity correction (OPC) method comprising:
obtaining a brute Jacobian by using a learning mask;
obtaining learning data from the brute Jacobian;
performing artificial neural network (ANN) learning by using the learning data to obtain a curvy neural Jacobian model;
receiving data on the target mask;
performing a curvilinear OPC on the target mask to obtain a first baseline curvilinear mask;
reducing a number of vertices of the first baseline curvilinear mask and converting the first baseline curvilinear mask into a multigon mask by using the vertices of the first baseline curvilinear mask;
extracting first geometric features from the multigon mask;
calculating a Jacobian between the multigon mask and an edge placement error (EPE) by using the curvy neural Jacobian model and the first geometric features; and
optimizing the multigon mask by using the Jacobian.

12. The OPC method of claim 11, wherein the obtaining of the brute Jacobian comprises:
receiving data on the learning mask;
obtaining a second baseline curvilinear mask for the learning mask;
reducing a number of vertices of the second baseline curvilinear mask and converting the second baseline curvilinear mask into a learning multigon mask by using the vertices of the second baseline curvilinear mask;
performing a first OPC simulation on the learning multigon mask;
extracting second geometric features from the learning multigon mask;
performing curve point perturbation at a control point of the learning multigon mask;
performing a second OPC simulation on the learning multigon mask; and
deriving the brute Jacobian between the learning multigon mask and EPE,
wherein, after the deriving of the brute Jacobian, when a set criterion is satisfied, the obtaining of the brute Jacobian ends, and when a set criterion is not satisfied, the obtaining of the brute Jacobian proceeds to extracting the second geometric features.

13. The OPC method of claim 12, wherein:
the second geometric features are used as input learning data of the ANN learning, and
the brute Jacobian is used as output learning data of the ANN learning.

14. The OPC method of claim 12, wherein:
the second geometric features are obtained based on a relative relationship between a control point of the learning multigon mask and a surrounding evaluation point affected by perturbation of the control point, and
the perturbation is calculated by using a center of mass and is used for calculating the second geometric features.

15. The OPC method of claim 11, wherein, in the optimizing of the multigon mask,
the multigon mask is optimized by using gradient descent, and
accelerated mask optimization is applied to the multigon mask optimization.

16. A mask manufacturing method comprising:
performing an OPC method using a curvy neural Jacobian model on a target mask to obtain an OPC layout;
performing optical rule check (ORC) on the OPC layout;
transferring a final OPC layout passing the ORC as mask tape-out (MTO) design data;
preparing mask data based on the MTO design data; and
exposing a mask substrate based on the mask data,
wherein, in the obtaining of the OPC layout, the curvy neural Jacobian model is obtained through ANN learning and a predicted value by the curvy neural Jacobian model is applied to mask optimization.

17. The mask manufacturing method of claim 16, wherein the obtaining of an OPC layout comprises:
obtaining the curvy neural Jacobian model through the ANN learning using learning data;
obtaining a first baseline curvilinear mask and reducing vertices of the first baseline curvilinear mask to convert the first baseline curvilinear mask into a multigon mask;
extracting first geometric features from the multigon mask;
calculating a Jacobian between a multigon mask and an edge placement error (EPE) by using the curvy neural Jacobian model and the first geometric features; and
optimizing the multigon mask through gradient descent by using the Jacobian.

18. The mask manufacturing mask of claim 17, wherein the obtaining of the curvy neural Jacobian model comprises:
obtaining a brute Jacobian for a learning mask;
obtaining the learning data from the brute Jacobian;
performing the ANN learning by using the learning data; and
deriving the curvy neural Jacobian model.

19. The mask manufacturing mask of claim 18, wherein the obtaining of the brute Jacobian comprises:
receiving data on the learning mask;
obtaining a second baseline curvilinear mask for the learning mask;
reducing a number of vertices of the second baseline curvilinear mask and converting the second baseline curvilinear mask into a learning multigon mask by using the vertices of the second baseline curvilinear mask;
performing a first OPC simulation on the learning multigon mask;
extracting second geometric features from the learning multigon mask;
performing curve point perturbation at a control point of the learning multigon mask;
performing a second OPC simulation on the learning multigon mask; and
deriving the brute Jacobian between the learning multigon mask and EPE,
wherein, after the deriving of the brute Jacobian, when a set criterion is satisfied, the obtaining of the brute Jacobian ends, and when a set criterion is not satisfied, the obtaining of the brute Jacocbian proceeds to extracting the second geometric features.

20. The mask manufacturing mask of claim 19,
wherein:
the second geometric features are obtained based on a relative relationship between a control point of the learning multigon mask and a surrounding evaluation point affected by perturbation of the control point, and
the perturbation is calculated by a center of mass and is used for calculating the second geometric features.
